(19) United States
(12) Patent Application Publication
(10) Pub. No.: US 2007/0125526 A1
(43) Pub. Date: Jun. 7, 2007

(54) COOLING DEVICE FOR ELECTRONIC COMPONENTS

(75) Inventors: Kaoru SATOU, Fukuoka (JP); Haruhiko KOUNO, Fukuoka (JP); Seiji Manabe, Fukuoka (JP); Masaaki Arita, Fukuoka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/564,531

(22) Filed: Nov. 29, 2006

(30) Foreign Application Priority Data
Dec. 2, 2005 (JP) 2005-349035

(51) Int. Cl. H01L 23/467; F24H 3/02

(52) U.S. Cl. 165/121

(57) ABSTRACT

An inflow nozzle is disposed perpendicularly to plate-shaped fins of a heat-receiving section which is caused to face a heat-generating body to be cooled to draw heat therefrom, and portions of the plate-shaped fins are formed in a substantially V-shape or a substantially U-shape. Moreover, by selecting a proper dimension ratio of the thickness of a heat-receiving plate facing the heat-generating body and the length of the heat generating body, the heat absorption performance of the cooling device can be improved, and the cooling of the electronic component which generates high-temperature heat can be performed efficiently.

### BACKGROUND

The present invention relates to a cooling device for electronic components to be used for cooling heat-radiating semiconductor devices, such as a micro-processing unit (hereinafter referred as ‘MPU’) used in a personal computer, or electronic components having other heat-radiating parts.

In recent years, in electronic apparatuses, high integration of electronic components, such as semiconductors, realization of high clock frequency, and the like, cause increasing of heat radiation. In order to secure normal operation of electronic components against the increase heat radiation, it becomes important how to maintain the temperature of each electronic component within an operational temperature range.

However, conventional air-cooling systems in which a heat sink is combined with a fan which are increasingly undergoing lack of the capability to cool electronic components with a high calorific value. Therefore, a highly efficient cooling device with higher capability which circulates refrigerant, as disclosed in Patent Document 1, is proposed.

Generally, in cooling a heat-generating body with high heat value, such as an MPU, a method of radiating the heat absorbed in a heat-receiving section into air from a heat-radiating section having large area is adopted.

Here, a conventional technique disclosed in U.S. Pat. No. 6,333,849 will be described with reference to FIGS. 9A, 9B, 10A and 10B.

FIG. 9A is a view showing the configuration of a conventional cooling device, and FIG. 9B is a view showing a heat-receiving section of the conventional cooling device. Generally, such a cooling device, as shown in FIG. 9A, is composed of a heat-receiving section 1 which removes heat from a heat-generating body 2, a flow channel which carries the refrigerant which has received heat from the heat-generating body 2, a pump 13 which moves the refrigerant, and a heat-radiating section 11 which radiates the heat from the refrigerant. As for the main cooling principle of the cooling device, the following method is adopted. That is, as shown in FIG. 9A, first, the heat generated in the heat-generating body 2 is transferred to the interior of the heat-receiving section 1, and is exchanged with the refrigerant circulating in the interior, whereby the temperature of the refrigerant rises. Next, the refrigerant is carried to the heat-radiating section 11 through the flow channel 8 by the pump 13, thereby elevating the temperature of the heat-radiating section 11. Next, the air from the fan 10 loaded with the heat-radiating section is sent to and heat-exchanged with the surface of the heat-radiating section 11 whose temperature has been elevated, whereby the heat of the heat-radiating section is radiated into air.

In recent years, with miniaturization (thinning in a manufacturing process) of electronic components, the size of a heat-generating body itself also tends to become small, and the thermal density per unit area goes on increasing. Therefore, the cooling performance of a cooling device is determined by both the performance of a heat-receiving section and the performance of a heat-radiating section, and particularly realization of high performance of the heat-receiving section becomes a big task to be achieved. This means that, if the heat-generation area is reduced to 50 mm² due to thinning in an electronic component manufacturing process even in a cooling device which has temporarily cooled a heat-generating body with an area of 100 mm² which generates a heat of 100 W, since the thermal density is doubled, lack of the heat absorption performance occurs, and thus the heat-generating body cannot be cooled by such a cooling device.

Moreover, the structure as shown in FIG. 9B is adopted in the above-mentioned heat-receiving section using the method of circulating refrigerant as shown in FIG. 9A. In this structure, performance enhancement is contrived by proving a conduit for allowing refrigerant to be circulated therethrough in a metal (for example, copper, aluminum, or the like) having high thermal conductivity. However, even in this case, the efficiency of exchange of the heat from the metal to the refrigerant inside the heat-receiving section greatly depends on the area of the inner wall of the conduit. Thus, there are many cases that simply disposing the conduit inside the heat-receiving section results in small heat-receiving area, and consequently sufficient performance cannot be obtained. Therefore, it is considered that lack of the performance will become more conspicuous due to a reduction in the size of a heat-generating body in future.

Therefore, another conventional technique which has been contrived as a method of further enhancing the heat absorption performance of the heat-receiving section is a method of arranging plate-shaped fins 4a parallel to one another in a heat-receiving section, as shown in FIGS. 10A and 10B. This method, as shown in these drawings, results in a configuration in which a number of the plate-shaped fins 4a are erected on a heat-receiving plate 3 at certain intervals. Since this configuration ensures larger heat exchange area than that of FIG. 9B, it is suggested as a configuration from which higher heat absorption performance can be obtained.

However, in electronic components such as semiconductors, due to further development of high performance, the fact that heat generation tends to become large increasingly and thermal density tends to rise is as mentioned previously. In a case where the conventional cooling device of FIG. 9 is used, even a situation that it is difficult to perform sufficient cooling happens. As the measures about these problems, a heat-receiving section shown in FIG. 10A has been devised. A structure in which the number of the plate-shaped fins 4a is increased and thereby larger heat exchange area is ensured in order to ensure high performance is adopted in this heat-receiving section. In this case, as shown in FIG. 10B, the heat-receiving section is configured to form a stream that refrigerant passes between the fins from an inlet 5, and flows out to an outlet 6.

However, even in this configuration, if the number of the plate-shaped fins 4a increases up to a certain number, heat exchange area is increased, which results in an improvement in performance, but if the number of the fins increases beyond a certain number, a problem that the performance degrades may occur instead. This is because, if the number of the fins increases, the interval between the fins becomes narrow and the pressure loss of the refrigerant increases, and therefore the flow rate decreases instead, and the performance also degrades. That is, an increase in the heat exchange area and ensuring of the flow rate of refrigerant are in an offset relationship to each other, and thus there is no alternative but to select moderate conditions in the present circumstances.

Moreover, the method of increasing the number of fins has a problem in that the output of a pump is required to be increased in consideration of a sudden increase in the pressure loss resulting from the increase in the number of fins, and consequently the size of the pump should be increased inevitably, which may result in an increase in the size of the whole device.

### SUMMARY

The invention has been made to solve the above problems. It is therefore an object of the invention to provide a cooling device for electronic components capable of bringing out the maximum performance of a heat-receiving section for efficiently absorbing the heat generated from a heat-generating body, and having excellent cooling performance.

According to an aspect of the invention, there is provided a cooling device including a closed circulating path for circulating refrigerant, in which a heat-radiating section, a heat-receiving unit having a heat-receiving section, and a pump are provided, wherein the heat-receiving unit is caused to contact a heat-generating body to draw heat from the heat-generating body by a heat-exchanging action with the refrigerant within the heat-receiving section, the refrigerant is circulated and carried through the closed circulating path by the pump, and the heat is radiated from the heat-radiating section. Here, the heat-receiving section has an inlet which allows the refrigerant to flow in therethrough, the heat-receiving section which receives the heat of the heat-generating body to transfer the heat to the refrigerant, and an outlet for the refrigerant, the heat-receiving section has a heat-receiving plate which receives the heat of the heat-generating body, a plurality of plate-shaped fins which transfers the heat received by the heat-receiving plate to the refrigerant, and a cover which covers the fins, and the cover is opened at both ends of the fins, and has an inflow nozzle which is provided above the fins and connected with the inlet of the heat-receiving unit.

As described above, according to the cooling device of this embodiment, generation of a stagnation region can be prevented by providing a plurality of plate-shaped fins and a cover covering the fins in a heat-receiving section, selecting the optimal position and direction of a refrigerant inflow nozzle to the heat-receiving section, and partially changing the shape of the plate-shaped fins. Moreover, if the size of a heat-generating body and the size of the heat-receiving plate of the heat-receiving section are approximate to each other, it is possible to provide a cooling device for electronic components capable of bringing out the maximum performance of the heat-receiving section and having excellent cooling performance by adopting a proper dimension ratio range of the thickness h of the heat-receiving plate and the length L of the heat-generating body.

### BRIEF DESCRIPTION OF THE DRAWINGS

FIG. 1A is a perspective view showing a case in which a cooling device in Embodiment 1 of the invention is arranged within a housing of a personal computer (PC), and FIG. 1B is an enlarged view showing the structure of a heat-receiving unit.

FIG. 2A is a perspective view showing a heat-receiving section of the cooling device in Embodiment 1 of the invention, and FIG. 2B is a lateral streamline view of the heat-receiving section.

FIG. 3A is a graph showing the comparison between the effects of reducing a pressure loss P generated with respect to a fixed flow rate Q, when a heat-receiving section of a conventional example and the heat-receiving section in Embodiment 1 of the invention are used, and FIG. 3B is a graph showing the relationship between the flow rate P and the pressure loss Q when the same pump is used.

FIG. 4A is a lateral streamline view showing the positional relationship between the heat-receiving section and an inflow nozzle in Embodiment 1 of the invention, and FIG. 4B is a graph showing the influence of the position of the inflow nozzle on the thermal resistance when a fixed flow rate Q of refrigerant is caused to flow into the heat-receiving section in Embodiment 1 of the invention.

FIG. 5A is a perspective view of another heat-receiving section in Embodiment 2 of the invention, and FIG. 5B a lateral streamline view of the heat-receiving section in Embodiment 2 of the invention.

FIG. 6A is a lateral streamline view inside another heat-receiving section in Embodiments 1 and 2 of the invention, and FIG. 6B is a graph showing the relationship between a fin height and a standardized velocity ratio in the vicinity of another heat-receiving plate in Embodiments 1 and 2 of the invention.

FIG. 7A is a graph showing the comparison between the effects of reducing a pressure loss P generated with respect to a fixed flow rate Q, when examples of the heat-receiving sections in Embodiments 1 and 2 of the invention are used, and FIG. 7B is a graph showing the relationship between the flow rate P and the pressure loss Q when the same pump is used.

FIG. 8A is a lateral streamline view inside a heat-receiving section in Embodiment 3 of the invention, and FIG. 8B is a graph showing the ratio of the width of the heat-generating body and the thickness of the heat-receiving plate.

FIG. 9A is a view showing the configuration of a conventional cooling device, and FIG. 9B is a view showing a heat-receiving section of the conventional cooling device.

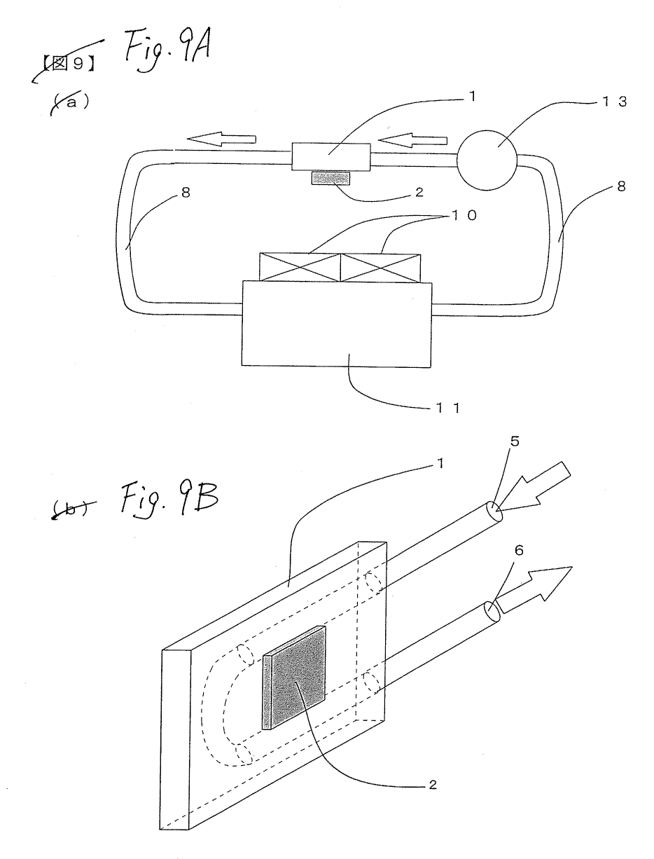

FIG. 10A is a view showing the configuration of another conventional cooling device, and FIG. 1 OB is a view showing a heat-receiving section of the conventional cooling device.

FIG. 11 is a graph showing a change in standardized thermal resistance when the size of a heat-generating body is changed.

### DETAILED DESCRIPTION

Hereinafter, embodiments of the invention will be described with reference to the accompanying drawings.

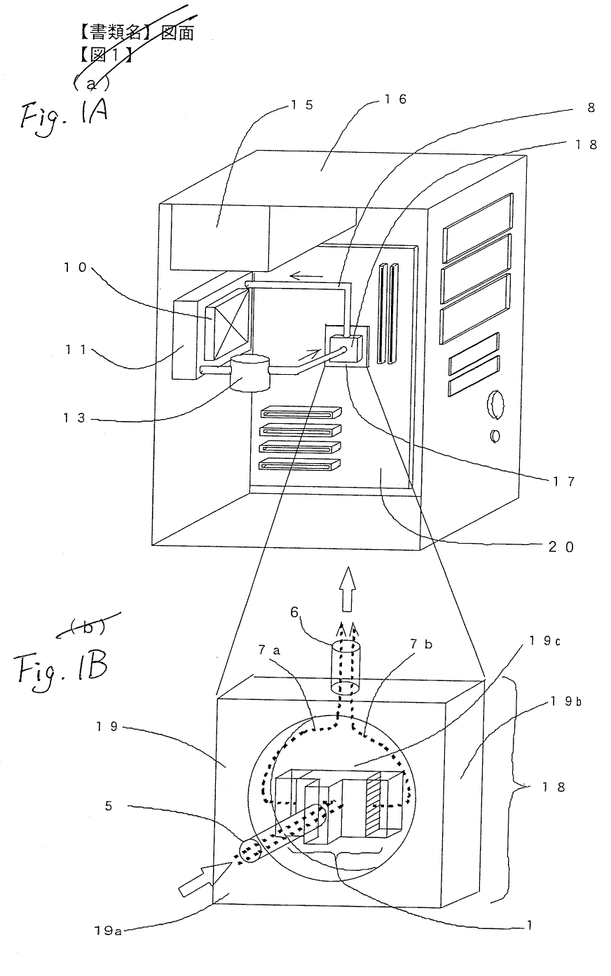

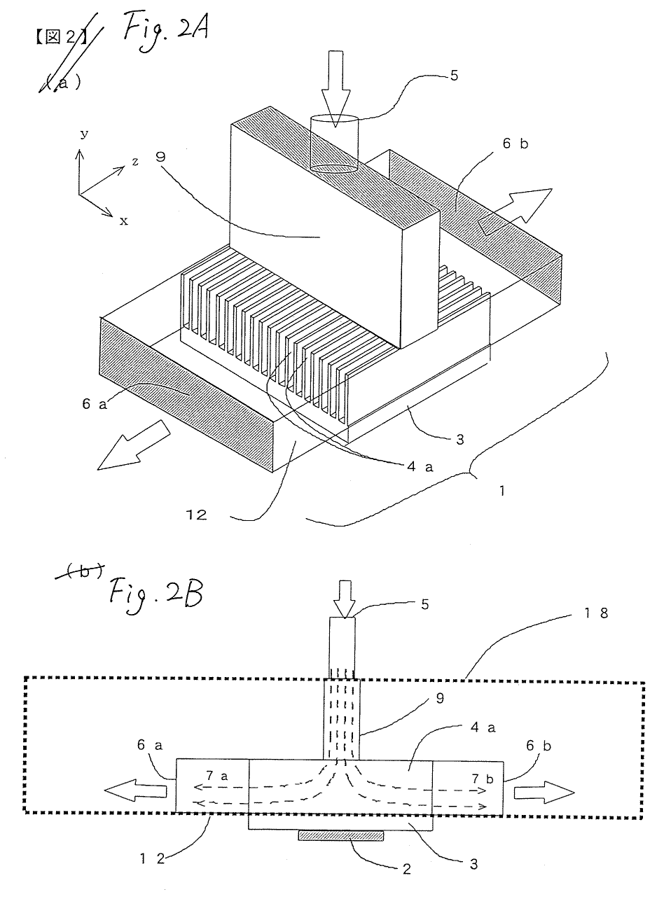

FIGS. 1A and 1B are respectively a perspective view showing a case in which a cooling device in Embodiment 1 of the invention is arranged within a housing of a personal computer (hereinafter referred to as ‘PC’), and a structural view of a heat-receiving unit. In FIG. 1A, reference numeral 16 represents a PC housing within which the cooling device of the invention together with PC components such as a power supply unit 15 and a mother board 20 are arranged. The cooling device of the invention is composed of three main components, i.e., a heat-receiving unit 18 including a heat-receiving section 1, a heat-radiating section 11, and a pump 13 which circulates refrigerant, and a flow channel 8 which connects the three main components together. In actual cooling, first, refrigerant is delivered from the pump 13, and flows into the heat-receiving unit 18 which receives heat from an inlet 5 through the flow channel 8. The heat-receiving unit 18 faces a heat-generating body 2 (refer FIG. 2B) mounted on the heat-generating body socket 17, and the heat-receiving section 1, as shown in FIG. 1B, which receives heat, is disposed inside the heat-receiving unit 18. In the heat-receiving unit 18, the inlet 5 to be connected to an inlet of the flow channel 8 is provided in an upper part 19a of a unit cover 19, and an outlet 6 to be connected to an outlet of the flow channel 8 is provided in a sidewall 19b of the unit cover 19. Moreover, the heat-receiving section 1 is liquid-tightly attached to a bottom part 19c of the unit cover 19. Here, FIG. 1B is a perspective view showing that a portion of the unit cover 19 is removed from the heat-receiving unit 18.

Refrigerant flows into a middle part of a plurality of plate-shaped fins 4a of the heat-receiving section 1, which are arranged substantially parallel to one another, via an inflow nozzle 9, branches off to the right and left like streamlines 7a and 7b, and then flows towards to the outlet 6. At this time, the refrigerant receives heat when it passes between the fins whose temperature has been elevated with the heat from the heat-generating body 2, thereby cooling the heat-generating body 2. Next, the refrigerant which has received the heat flows into the heat-radiating section 11 through the flow channel 8 in an arrowed direction from the outlet 6 of the heat-receiving unit 18, thereby raising the temperature of the heat-radiating section 11. Then, the air from a fan 10 equipped with a heat-radiating section is sent towards the surface of the heat-radiating section 11 whose temperature has been elevated, to exchange heat with the surface, whereby the heat is radiated into air.

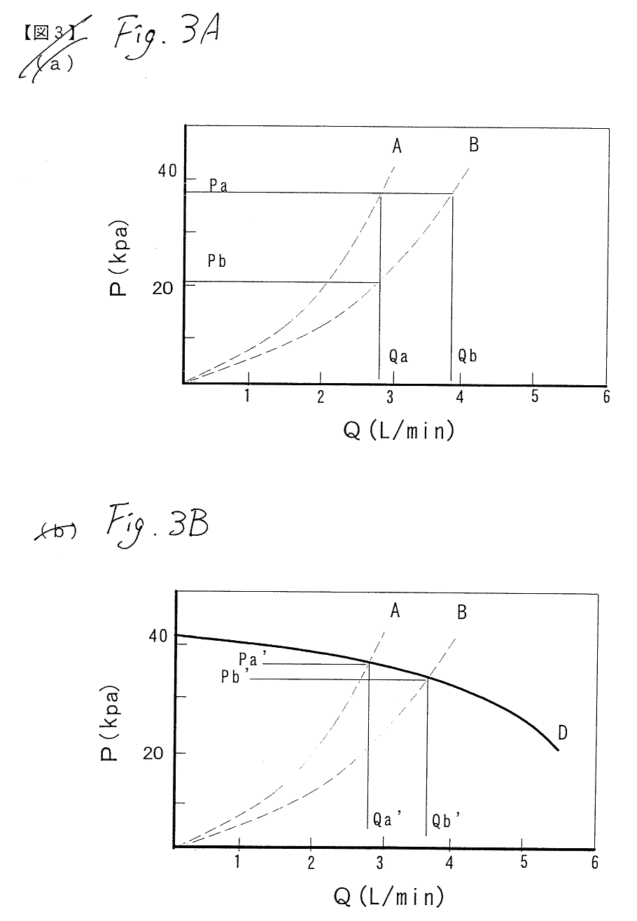

Next, referring to FIGS. 2A and 2B and FIG. 3, more detailed structure and characteristics of the heat-radiating section 11 will be described. FIGS. 2A and 2B are respectively a perspective view and a lateral streamline view showing the heat-receiving section 1 of the cooling device in Embodiment 1 of the invention. In FIG. 2A, reference numeral 1 represents the whole heat-receiving section 1. Reference numeral 2 represents a heat-generating body (refer to FIG. 2B), and reference numeral 3 represents a heat-receiving plate which comes into contact with the heat-generating body 2 to absorb heat. The heat-receiving plate is made of, for example, a material, such as copper or aluminum, having small thermal resistance, is made thicker than the unit cover 19, and protrudes from the bottom part of the unit cover. This makes clear the position where the heat-receiving plate is attached to the heat-generating body 2, and consequently it becomes easy to attach the heat-generating body 2. Reference numeral 5 represents an inlet for allowing refrigerant to flow into the heat-receiving section 1, and one end of the inlet is connected to the flow channel 8. Reference numeral 4a represents a plate-shaped fin disposed on the heat-receiving plate 3. The plate-shaped fin is made of, for example, a thermal conductive material, such as copper or aluminum, and a plurality of the plate-shaped fins are arranged at predetermined intervals substantially parallel to one another. Reference numeral 12 represents a heat-receiving cover which covers the plate-shaped fins 4a. The heat-receiving cover is longer than the length of the plate-shaped fins 4a in a Z direction, and flow channels are defined at both ends of the plate-shaped fins 4a by the heat-receiving cover 12. Both ends of the heat-receiving cover 12 in a direction (z direction) along the plate-shaped fins 4a are opened to form outlets 6a and 6b for refrigerant. An inflow nozzle 9 into which refrigerant flows is loaded on the heat-receiving cover 12 in the vicinity of a longitudinal middle part of the plate-shaped fins 4a. Reference numeral 9 represents an inflow nozzle which is loaded on the heat-receiving cover 12 for distributing the refrigerant, which has flown from the inlet 5, to each of the plate-shaped fins 4a. One end of the inflow nozzle is connected to the inlet 5. The width of the inflow nozzle 9 is approximately the same as the arrangement width of the plurality of plate-shaped fins 4a, and is loaded substantially vertically on the heat-receiving cover 12. Although the present embodiment has been described about the case where the inflow nozzle 9 is fabricated separately and loaded on the heat-receiving cover 12, the inflow nozzle 9 may be fabricated integrally with the heat-receiving cover 12.

Moreover, reference numeral 18 indicated by broken lines represents the heat-receiving unit 18 of FIG. 1 which is schematically shown. An opening is formed in the bottom part 19c of the unit cover 19, and the heat-receiving plate 3 of the heat-receiving section 1 is inserted through the opening of the bottom part of the unit cover 19, and is liquid-tightly attached thereto by means of soldering, press-fitting, welding, or the like. Here, the heat-generating body 2 includes heat-radiating electronic components, such as semiconductors including ICs, LSIs, and MPUs, and transistors.

In the heat-receiving section 1, as previously mentioned, refrigerant flows into the inflow nozzle 9 from the inlet 5, and is distributed to each of the plate-shaped fins 4a within the inflow nozzle 9. The inflow nozzle 9 is disposed in the middle of the plate-shaped fins 4a in the longitudinal direction (z direction), and the refrigerant which has flown between the fins 4 takes a route in which the refrigerant branches off to the right and left from the longitudinal middle part of the plate-shaped fins 4a, and the branching refrigerants pass through paths as indicated by streamlines 7a and 7b, and flow out of the two outlets 6a and 6b of the heat-receiving cover 12. When the refrigerant passes between the fins, heat exchange is performed to cool the heat-generating body.

In addition, in a coordinate system used in FIG. 2, the x direction represents an arrangement width direction of the plate-shaped fins 4a, y direction represents a direction in which refrigerant flows into the plate-shaped fins 4a, and z direction represents a longitudinal direction of the plate-shaped fins 4a, and all the following descriptions will be made using the same coordinate system.

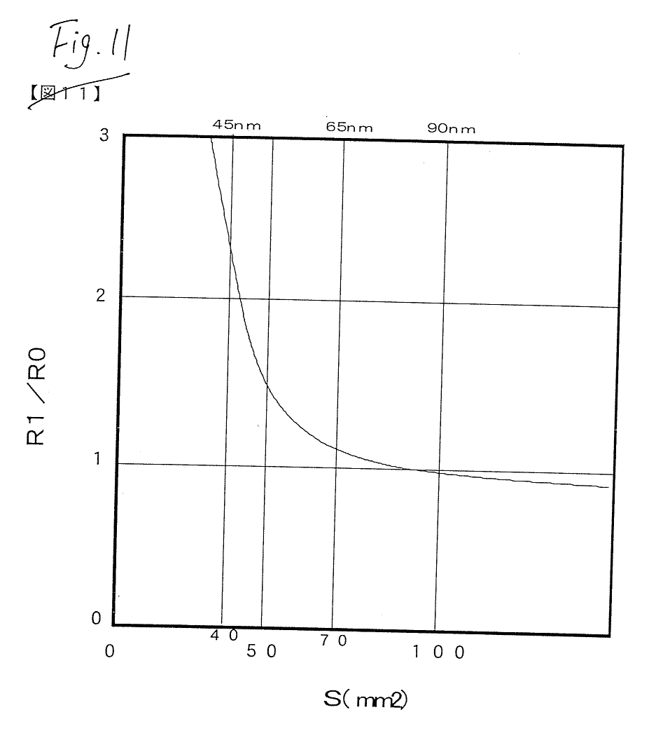

Generally, in the heat-receiving section 1 which faces the heat-generating body 2, heat is absorbed from a contact surface (heat-receiving surface) between the heat-generating body 2 and the heat-receiving plate 3 and transferred to the fins, and the heat is lost by heat exchange with the refrigerant which flows between the fins, thereby cooling the heat-generating body 2. However, the size of the heat-generating body 2 has been reduced with recent miniaturization and cost reduction. Even if a calorific value itself is scarcely changed, the density of the heat (calorific value per unit area) from the heat-generating body 2 will sharply increase inversely with the size. This point means a significant decline in heat absorption performance as mentioned previously. The cause of the significant decline is shown in a graph of FIG. 11. This graph is a graph plotted by experimentally obtaining changes in thermal resistance when the same cooling device is used and the calorific value is fixed, and the size of a heat-generating body is changed. The abscissa axis represents the size (area S: mm²) of the heat-generating body 2, and the ordinate axis represents a standardized thermal resistance ratio (R1/R1) that is the ratio of a thermal resistance RO of the cooling device when the size of the heat-generating body is set to 100 mm² is defined as RO, and a thermal resistance R1 of the cooling device when the size of the heat-generating body is reduced. Moreover, examples of the generation shift of a minimum line width of a semiconductor process required to realize each size in future is also appended to an upper abscissa axis. It can be understood from this graph that, when the size of the heat-generating body is reduced, the thermal resistance also degrades sharply. This is caused by an increase in heat density that accompanies a reduction in the size of the heat-generating body as mentioned previously, and this means a substantial decline in the heat absorption performance of the cooling device. Moreover, the generation shift of the minimum line width mentioned herein is typically performed in two or three years. Even if an increase in the number of semiconductor elements during that time is taken into consideration, it is said that the size is reduced to about 70% in one generation. Thus, a problem that it becomes difficult to ensure the heat absorption performance enough to cope with an increase in heat density by this generation shift is greatly exposed.

Accordingly, it is needless to say that enhancing the performance of the heat-receiving section against this problem is a pressing need. However, this requires pressure loss to be reduced in order to ensure a large flow rate of refrigerant while ensuring a large heat exchange area of the heat-receiving section, as mentioned previously. Therefore, a cooling device having excellent heat absorption performance is realized in the invention by adopting a method of causing refrigerant to flow in vertically towards the center of a heat-generating body from above fins having plate-shaped structure, thereby ensuring both large heat exchange area and large flow rate by virtue of a reduction in pressure loss.

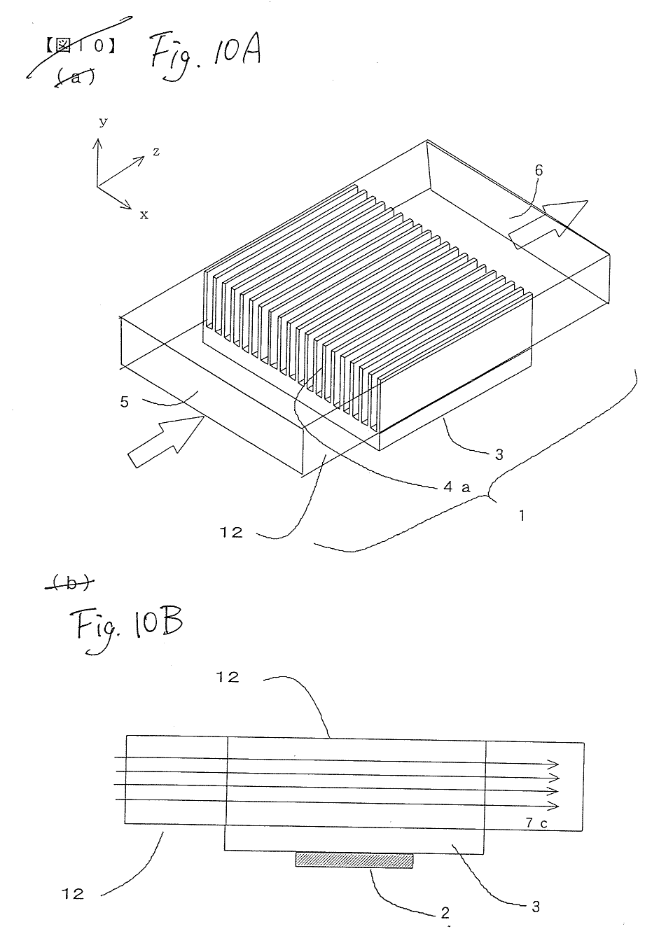

As mentioned previously, FIG. 2B shows that refrigerant flows into approximately the center of the plate-shaped fins above the fins from the inflow nozzle 9, so that a refrigerant stream separated into the right and left streamlines 7a and 7b can be formed. In this configuration, as shown in FIG. 2A, if the cross-sectional areas (shaded areas) of the inflow nozzle 9 and the outlets 6a and 6b are made equal to each other, as compared with a streamline 7c in a case where refrigerant is drawn out in one direction as in the related art of FIG. 10A, the length of the streamlines 7a and 7b which pass between the fins is reduced by about half and the area of the outlets is doubled because the refrigerant branches off to the right and left. Therefore, the pressure loss can be significantly reduced by about half This results in a significant increase in flow rate.

Furthermore, an example of a pressure loss reducing effect in Embodiment 1 will now be described while presenting actual measurement values. FIG. 3A shows the relationship between the flow rate and the pressure loss for every heat-receiving section, similarly to FIG. 2A. Here, line A represents a line when a conventional heat-receiving section shown in FIG. 10 is used, and line B represents a line when the heat-receiving section in Embodiment 1 shown in FIG. 2 is used. From this drawing, the pressure losses when refrigerant is caused to flow at a flow rate Qa of 2.8 L/min, using the heat-receiving sections in the conventional example and Embodiment 1, are Pa (38 kpa) and Pb (21 kpa), respectively. It could be confirmed that the pressure loss Pb in Embodiment 1 is reduced to 55% (Pb/Pa =0.55) with respect to Pa of the conventional example by virtue of inflow of the refrigerant from above the center of the fins. Accordingly, if a pump having the same performance (developed pressure) Pa is used for these heat-receiving sections, the flow rate will increase to a point where it intersect line B as compared with the conventional example of line A. That is, the increasing rate of the flow rate becomes an increase by 39% (Qb/Qa =3.9/2.8) in Embodiment 1 of line B, which is a considerable increase in flow rate. However, since the pressure developed from the pump is not fixed with respect to the flow rate, the flow rate does not increase as mentioned previously. This point is shown in FIG. 3B.

FIG. 3B shows that a P-Q curve (line D) of a pump is added to the graph of FIG. 3A. In this drawing, an operational point of each heat-receiving section when the pump is used is represented by a point where the P-Q curve (line D) of the pump intersects each pressure loss curve. That is, since the increasing rate of the flow rate of each heat-receiving section becomes an increase by 32% in the case of line B (Qb′/Qa′=3.7/2.8), and the P-Q curve of the pump is not fixed, there is no increase as much as that shown in FIG. 3A. However, this increasing rate of 32% makes it possible to realize a great enhancement in performance.

In addition, the maximum shutoff pressure of the pump used in Embodiment 1 is 42 kpa. Moreover, in the configuration shown in FIG. 2, the dimensions of the erected plate-shaped fins of the heat-receiving section are 12 mm ×5 mm ×12 mm in x, y, and z directions, and the dimension between the fins is 0.2 mm. In order to enhance the performance of a heat-receiving section, generally, it is necessary to lead a larger flow rate of refrigerant between fins while increasing the number of fins of the heat-receiving section and ensuring larger heat exchange area. However, as mentioned previously, the relationship between an increase in the heat exchange area of fins and an increase in flow rate is a trade-off relationship in which they are offset by each other. Therefore, using the method according to the invention, the offset relationship can be abolished, and high heat absorption performance can be realized.

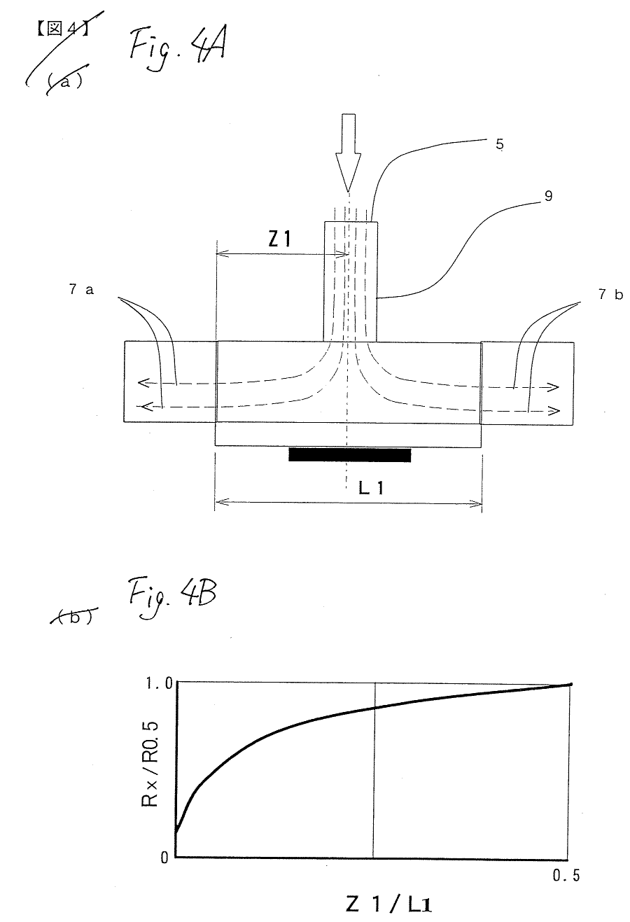

Next, FIG. 4A is a lateral streamline view showing the positional relationship between the heat-receiving section and the inflow nozzle in Embodiment 1 of the invention, and FIG. 4B is a graph showing the influence of the position of the inflow nozzle on the thermal resistance when a fixed flow rate Q of refs' rigerant is caused to flow into the heat-receiving section in Embodiment 1 of the invention.

In FIG. 4B, the abscissa axis represents a ratio (Z1/Z2) of an inflow position Z1 of the inflow nozzle 9 in the longitudinal direction (z direction) of the fins, and the length L of the heat-generating body 2 on which the fins 4a are erected, and the ordinate axis represents a standardized thermal resistance (Rx/R0.5) that is the ratio of a thermal resistance R0.5 and a thermal resistance Rx in each inflow nozzle position, when the inflow nozzle position is in the middle (Z1/L1 =0.5). From this drawing, when the inflow nozzle position is in the middle (Z1/L1 =0.5), the flow rates of the refrigerant to the right and left are the same, and the maximum thermal resistance ratio is 1.0. It can also be understood that, when the position is biased, the thermal resistance ratio declines. That is, when the position is biased to one side, the pressure loss decreases and the flow rate increases on the side where the flow channel is shortened, whereas the flow rate decreases rapidly on the side where the pressure loss has increased. Therefore, the total heat absorption performance degrades. Accordingly, it can be said from this drawing that the middle inflow position is a position where the maximum performance can be exhibited.

In addition, when uniform inflow of refrigerant to between the fins is taken into consideration, it is desirable that the inflow width of the inflow nozzle 9 in the x direction is equal to the arrangement width of the plate-shaped fins 4a in the x direction. Moreover, in a case where the heat-receiving section 1 is actually loaded on the heat-receiving unit 18, if a method in which a hole for allowing the heat-receiving plate 3 of the heat-receiving 10 section 1 to protrude therethrough is formed in the unit cover 19, and the heat-receiving section 1 is fixedly fitted into the hole, the heat-receiving unit 18 can be manufactured at a comparatively low cost.

### EMBODIMENT 2

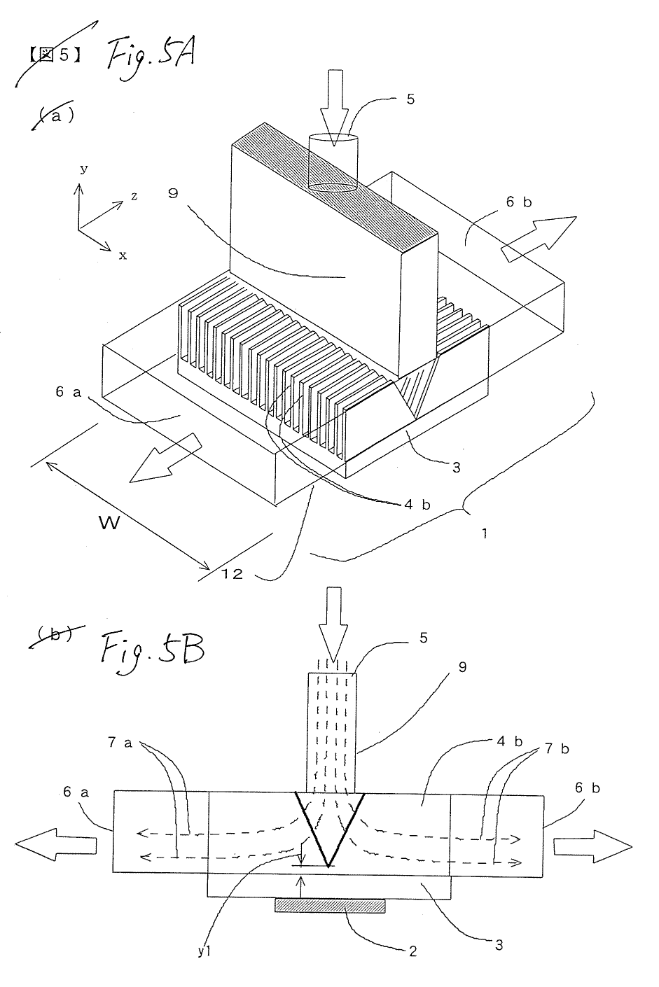

FIGS. 5A and 5B show an example of a cooling device in Embodiment 2 of the invention. FIGS. 5A and 5B are respectively a perspective view and a lateral streamline view of a heat-receiving section of the cooling device in Embodiment 2 of the invention. The configuration of FIG. 5A is almost the same as, but is different from the configuration of FIG. 2A, in that plate-shaped fins 4b arranged on the heat-receiving plate 3 has a substantially V-shaped notch shape in the middle thereof.

Since both large heat exchange area and large flow rate by virtue of a reduction in pressure loss can be ensured similarly to Embodiment 1 by adopting a method of causing refrigerant to flow vertically towards the middle of a heat-generating body from above the plate-shaped fins 4a having a substantially V-shaped notch, a cooling device having excellent heat absorption performance can be realized.

FIG. 5B is a lateral streamline view in a case where a substantially V-shaped notch is formed in the plate-shaped fins. Even in this case, characteristics of performance improvements similar to those described in FIG. 2B can be obtained. In particular, even in a case where the heat exchange area of the fins are increased by increasing the height of the fins, it is possible to lead refrigerant inflowing from the middle, to a position in the vicinity of and right above the heat-generating body, and consequently it is easy to ensure larger heat exchange area, by adopting a V-shaped structure having a wide notch width above such plate-shaped fins 4a. Therefore, it is possible to realize much higher heat absorption performance than that of Embodiment 1.

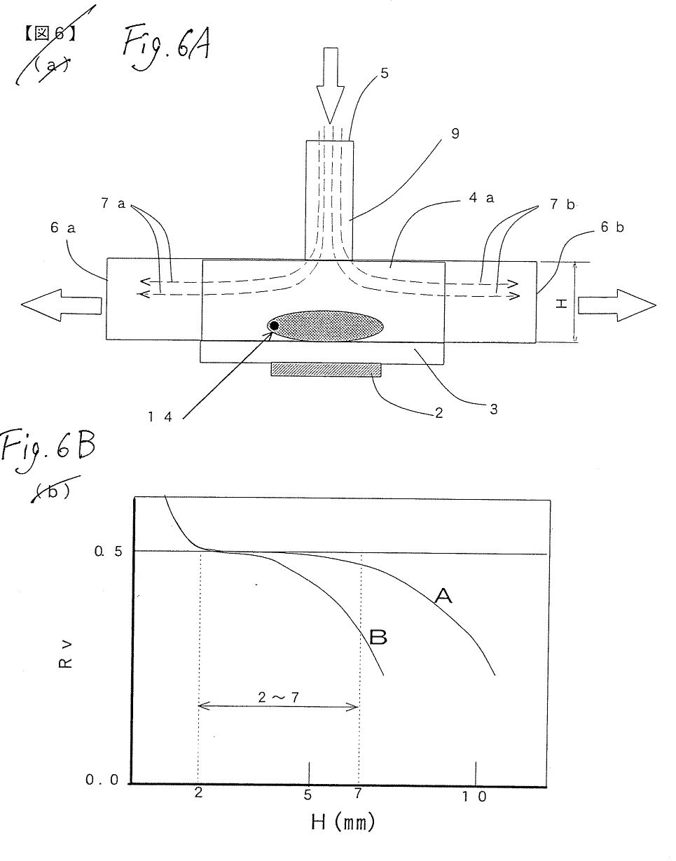

Generally, in a case where the height of the fins are simply increased so that larger heat exchange area may be ensured for the purpose of obtaining much higher performance in the structure shown in FIG. 2A, lateral streamlines of the heat-receiving section, as shown in FIG. 6A, do not reach the roots of the fins where the highest heat exchange can be expected. That is, if a fin height H exceeds a certain height in a state where a substantially V-shaped notch is not provided as shown in this drawing, the pressure loss in a refrigerant inflow direction increases. Therefore, the streamlines do not inherently reach a portion right above the heat-generating body to be cooled, but it is apt to be bent short of the portion to form a stagnation region 14 in the vicinity of and right above the heat-generating body. Since this stagnation region 14 has little heat exchange and thus causes performance degradation, it is necessary to minimize generation of the region. Therefore, a method of preventing generation of the stagnation region 14 and realizing high performance while increasing the fin height to ensure large heat exchange area is the method of forming a substantially V-shaped notch in a middle part of the plate-shaped fins as shown in Embodiment 2 of the invention. In addition, even if the V-shaped notch is a substantially U-shaped notch, almost the same effects can be obtained. Moreover, it is desirable that a height y1 between a substantially V-shaped bottom part and the heat-receiving plate 3 is smaller. This is because, if there is a margin in the pressure of a pump, y1 is increased so that larger fin area can be ensured, but there is a possibility that a larger pump size is still required which is not realistic choice. Moreover, as for the shape of the inflow nozzle 9 in this case, the inflow width of the inflow nozzle in the x direction is not necessarily the same as the arrangement width of the fins in the x direction so long as pressure loss is little and a sufficient flow rate of refrigerant to the V-shaped notch can be ensured.

FIG. 6B is a graph in which a height H of the plate-shaped fins is represented on the abscissa axis, and a flow velocity ratio (Rv=V7/V5) between a flow velocity V5 of the refrigerant inflowing from the middle and a flow velocity V7 (one outflow velocity) of the right and left separated streamlines 7a and 7b in the vicinity of and right above the heat-generating body is represented on the ordinate axis. Here, it is desirable that the outflow velocity V7 becomes about the flow velocity ratio Rv=0 that is just the half of the inflow velocity V5. This is because, if the flow velocity ratio Rv in the vicinity of and right above the heat-generating body is 0.5 (Rv=0.5), the cross-sectional area of an upper part of the inflow nozzle and the cross-sectional area of one outlet are almost the same, if Rv is greater than 0.5 (Rv≧0.5), the outflow velocity becomes high but the pressure loss also increases and thus the flow rate also decreases, and if Rv is smaller than 0.5 (Rv≦0.5), the flow velocity on the side of the outlet is too low and a sufficient heat transfer coefficient on the surfaces of the fins cannot be obtained, and consequently there is a possibility that all the above cases lead to performance degradation.

Moreover, assuming that the width (the width of a long side) of the inflow nozzle 9 in the x-direction and the width of the outlets 6a and 6b in the x direction are the same as the arrangement width W of the plate-shaped fins of FIG. 5A, a case where the width (the width of a short side) of the inflow nozzle 9 in the z direction is set to 5 mm and the height H of the plate-shaped fins 4a is also set to 5 mm will now be described. Here, line A represents ‘with V-shape’ and line V represents ‘with no V-shape’. It can be apparently understood that a flow velocity ratio near to Rv=0.5 is maintained to a greater height in line A (with V-shape) than that in line B (with no V-shape). If the fin height H is less than 2 mm, the flow velocity ratio rises rapidly, and performance degradation caused by a decrease in flow rate resulting from an increase in pressure loss is expected as mentioned previously. In the case of line B, a decline in the flow velocity ratio is observed from a fin height of about 3 mm, but a large decline in the flow velocity ratio is not observed up to about 7 mm.

Accordingly, this graph means that a fin height near to the flow velocity ratio Rv =0.5 is within a range of 2 to 7 mm, and a notch with V-shape can maintain a flow velocity ratio near to 0.5 up to a fin height where a larger heat exchange area is obtained.

In addition, although Embodiment 2 has been described about the case where the notch shape is a substantially V-shape, the similar effects can be obtained even if the notch shape may be a substantially U-shape, or a substantially trapezoidal shape formed by making an upper notch part of the plate-shaped fins 4a wider.

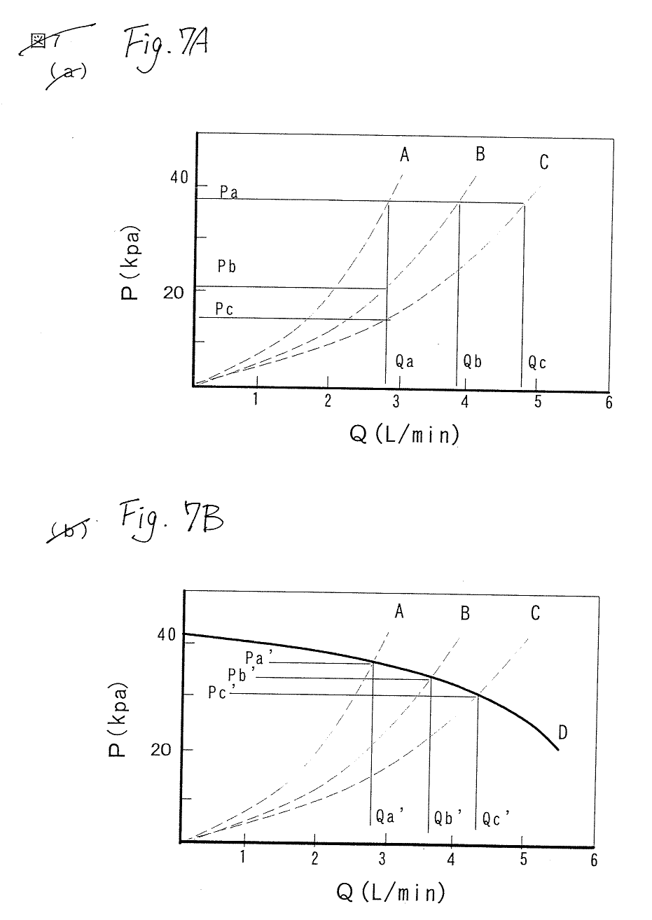

Moreover, an example of actual measurement values of a pressure loss reducing effect in Embodiment 2 will now be described. FIG. 7A shows the relationship between the flow rate and the pressure loss for every heat-receiving section, similarly to FIG. 3A. Here, line A represents a line when a conventional heat-receiving section shown in FIG. 10 is used, line B represents a line when the heat-receiving section in Embodiment 1 shown in FIG. 2 is used, and line B represents a line when the heat-receiving section in Embodiment 2 shown in FIG. 5 is used. From this drawing, the pressure losses when refrigerant is caused to flow at a flow rate Qa of 2.8 L/min, using the heat-receiving sections in the conventional example and Embodiments 1 and 2, are Pa (38 kpa), Pb (21 kpa), and Pc (14 kpa), respectively. It could be confirmed that, by virtue of inflow of the refrigerant from above the center of the fins, the pressure loss Pb in Embodiment 1 is reduced to 55% (Pb/Pa=0.55) with respect to Pa of the conventional example, and the pressure loss in Embodiment 2 is further lowered because a V-shaped notch is provided in the middle, i.e., is reduced to 33% (Pc/Pa=0.33) with respect to Pa. Accordingly, if a pump having the same performance (developed pressure) Pa is used for these heat-receiving sections, the flow rate will theoretically increase to points where it intersect line B and C as compared with the conventional example of line A. That is, the increasing rate of the flow rate becomes an increase by 39% (Qb/Qa=3.9/2.8) in Embodiment 1 of line B, and an increase by 71% (Qc/Qa=4.8/2.8) in Embodiment 2 of line c, both of which are considerable increases in flow rate.

However, since the pressure developed from the pump is not fixed with respect to the flow rate, the flow rate does not increase as mentioned previously. This point is shown in FIG. 7B.

FIG. 7B shows that a P-Q curve (line D) of a pump is added to the graph of FIG. 7A, similarly to FIG. 3A. In this drawing, an operational point of each heat-receiving section when the pump is used is represented by a point where the P-Q curve (line D) of the pump intersects each pressure loss curve. That is, since the increasing rate of the flow rate of each heat-receiving section becomes an increase by 32% in the case of line B (Qb′/Qa′=3.7/2.8), and an increase by 53% in the case of line C (Qc′/Qa′=4.3/2.8), and the P-Q curve of the pump is not fixed, there is no increase as much as that obtained in FIG. 7A. However, this increasing rate of 53% makes it possible to realize a greater enhancement in performance than Embodiment 1.

In addition, the specification of the pump used in Embodiment 2 and the dimensions of the erected plate-shaped fins of the heat-receiving section used in Embodiment 2 are the same as those of Embodiment 1.

### EMBODIMENT 3

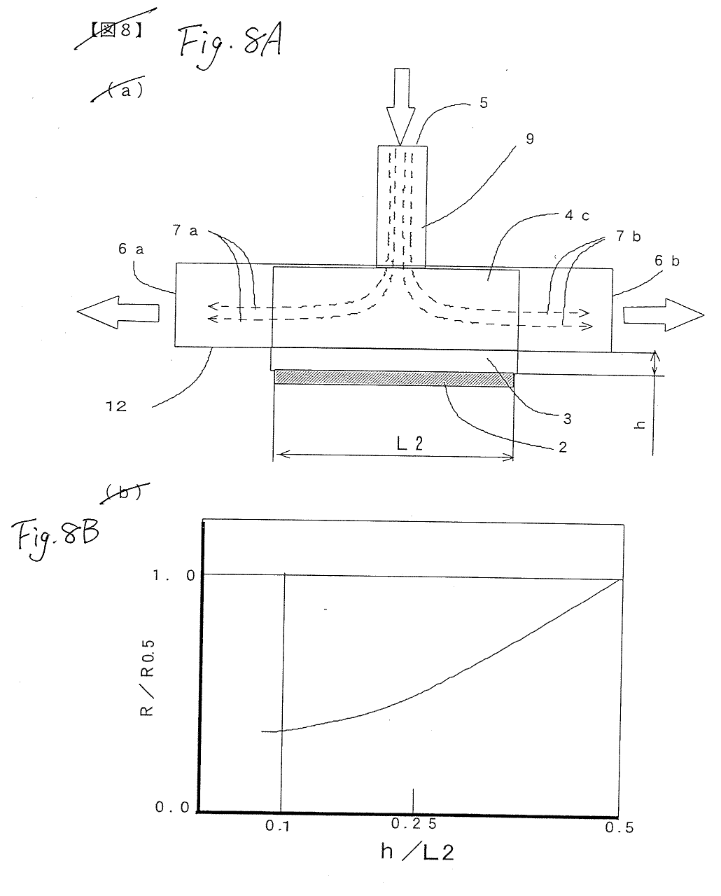

FIGS. 8A and 8B are respectively a lateral streamline view of the interior of a heat-receiving section in Embodiment 3 of the invention, and a graph showing the relationship between the ratio of the width of a heat-generating body and the thickness of a heat-receiving plate, and a standardized thermal resistance ratio. The configuration of FIG. 8A is basically the same as, but is different from that of FIG. 2A, in that a plurality of the plate-shaped fins 4c of the heat-receiving section are joined together, and the size of the heat-receiving plate 3 facing the heat-generating body 2 and the size of the heat-generating body 2 are relatively approximate to each other. Moreover, if it is assumed that the width of the heat-generating body 2 and the width of the heat-receiving plate 3 are almost the same, the abscissa axis of FIG. 8B represents a dimension ratio (T=h/L2) of the length L of the heat-generating body and the thickness h of the heat-receiving plate, which are shown in FIG. 8A, and the ordinate axis represents the ratio of a thermal resistance R0.5 when T=0.5, and a thermal resistance R when the thickness h of the heat-receiving plate is changed. From this drawing, when the size of the heat-receiving plate and the size of the heat-generating body are relatively approximate to each other, it can be understood that, as the dimension ratio T is gradually reduced from T=0.5, the thermal resistance becomes small in the vicinity of T=0.1. However, since the thickness h of the heat-receiving plate becomes too small in actuality in a dimension ratio T of T=0.1 or less, and therefore structural strength cannot be ensured, this dimension ratio cannot be adopted.

Accordingly, when the size of the heat-receiving plate and the size of the heat-generating body are relatively approximate to each other as mentioned previously, it is possible to realize low thermal resistance (high heat absorption performance) by maintaining the dimension ratio T in a range of T=0.1 to 0.5

As described above, in the cooling device for electronic components according to the embodiments of the invention, a vertical refrigerant inflow nozzle is disposed in the vicinity of a middle part of a plurality of plate-shaped fins which protrude towards the opposite side of the surfaces of the fins that face a heat-generating body within a heat-receiving section, and portions of the plate-shaped pins are formed in a substantially V-shape or a substantially U-shape, so that a main stream can be led to a region in the vicinity of and right above the heat-generating body while preventing generation of a stagnation region. Moreover, the dimension ratio (T=h/L2) of the thickness h of the heat-receiving plate and the length L2 of the heat-generating body is set to be within a range of T=0.1 to 0.5, so that the thermal resistance of a metal part contacting the heat-generating body can be minimized, and a cooling device for electronic components having high heat absorption performance can be realized.

According to the cooling device for electronic components of the invention, since the cooling device has high heat absorption performance, it is particularly suitable for cooling of electronic components with a high calorific value which accompanies high integration of MPUs or the like and realization of high frequency. It is noted that the foregoing examples have been provided merely for the purpose of explanation and are in no way to be construed as limiting of the present invention. While the present invention has been described with reference to exemplary embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular structures, materials and embodiments, the present invention is not intended to be limited to the particulars disclosed herein; rather, the present invention extends to all functionally equivalent structures, methods and uses, such as are within the scope of the appended claims.

The present invention is not limited to the above described embodiments, and various variations and modifications may be possible without departing from the scope of the present invention.

This application is based upon and claims the benefit of priority of Japanese Patent Application No. 2005-349035 filed on Dec. 2, 2005, the contents of which are incorporated herein by reference in its entirety.

What is claimed is:

1. A cooling device comprising:
a closed circulating path for circulating refrigerant, in which a heat-radiating section, a heat-receiving unit including a heat-receiving section, and a pump are provided,
wherein the heat-receiving unit is caused to contact a heat-generating body to draw heat from the heat-generating body by a heat-exchanging action with the refrigerant within the heat-receiving section,
the refrigerant is circulated and carried through the closed circulating path by the pump, and the heat is radiated from the heat-radiating section,
wherein the heat-receiving section has an inlet which allows the refrigerant to flow in therethrough, the heat-receiving section which receives the heat of the heat-generating body to transfer the heat to the refrigerant, and an outlet for the refrigerant,
the heat-receiving section has a heat-receiving plate which receives the heat of the heat-generating body, a plurality of plate-shaped fins which transfers the heat received by the heat-receiving plate to the refrigerant, and a cover which covers the fins, and
the cover is opened at both ends of the fins, and has an inflow nozzle which is provided above the fins and connected with the inlet of the heat-receiving unit.

2. The cooling device according to claim 1, wherein the inflow nozzle is disposed in the vicinity of a longitudinal middle part of the plurality of plate-shaped fins.

3. The cooling device according to claim 1, wherein the width of the inflow nozzle is equal to the arrangement width of the plurality of plate-shaped fins.

4. The cooling device according to claim 2, wherein the inflow nozzle is substantially perpendicular to the heat-receiving plate.

5. The cooling device according to claim 1, wherein a notched part having any one among a substantially V-shape, a substantially U-shape, and a substantially trapezoidal shape is formed in the middle part of the plate-shaped fins.

6. The cooling device according to claim 1, wherein the dimension ratio (T =h/L2) of the thickness h of the heat-radiating plate which joins the plate-shaped fins of the heat-receiving section together, and faces the heat-generating body, and the length L2 of the heat-generating body is within the range of 0.1 to 0.5.

7. The cooling device according to claim 1, wherein the length of the cover is equal to or greater than the length of the plate-shaped fins.

8. A cooling device comprising:
a closed circulating path for circulating refrigerant, in which a heat-radiating section, a heat-receiving unit including a heat-receiving section, and a pump are provided,
wherein the heat-receiving section is caused to contact a heat-generating body to draw heat from the heat-generating body by a heat-exchanging action with the refrigerant within the heat-receiving section,
the refrigerant is circulated and carried through the closed circulating path by the pump, and the heat is radiated from the heat-radiating section,
wherein the heat-receiving unit has one inlet which allows the refrigerant to flow thereinto, and two outlets from which refrigerant flow out.

9. The cooling device according to claim 8, wherein the inflow nozzle is disposed in the vicinity of a longitudinal middle part of the plurality of plate-shaped fins.

10. The cooling device according to claim 8, wherein the width of the inflow nozzle is equal to the arrangement width of the plurality of plate-shaped fins.
